(19) United States
(12) Patent Application Publication
(10) Pub. No.: US 2009/0060226 A1
(43) Pub. Date: Mar. 5, 2009

(54) AUDIO CIRCUIT FOR DISPLAY

(75) Inventors: HAI-YUN CHEN, Shenzhen (CN); XIAO-LIN GAN, Shenzhen (CN); YU-KUANG HO, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 11/965,763

(22) Filed: Dec. 28, 2007

(30) Foreign Application Priority Data
Aug. 28, 2007 (CN) 200710201488.4

(51) Int. Cl. H03G 3/00

(52) U.S. Cl. 381/107; 381/120

(57) ABSTRACT

An audio circuit arranged in a display includes an audio input connector configured to connect to an audio output connector of a computer to receive audio signals therefrom, an audio input circuit receiving the audio signals, an audio amplifier circuit connected to the audio input circuit to amplify the audio signals, an audio output circuit outputting the amplified audio signals, a first output connector connected to the audio output circuit, a volume adjusting circuit, a micro control unit (MCU) of a motherboard of the display connected to the volume adjusting circuit, and a speaker connected to the first output connector. The volume adjusting circuit receives a control signal from the MCU to control the volume adjusting circuit to adjust the audio signals, and the speaker receives the adjusted audio signals.

### BACKGROUND

1. Field of the Invention

The present invention relates to audio circuits, and particularly to an audio circuit for a display.

2. Description of Related Art

Nowadays, displays are used widely in many fields, especially in computer system. When a user uses a computer and a display to watch a movie or other video files, the user generally needs to use an external audio device to listen to the sound of the movie. However, the external audio device occupies space.

What is desired, therefore, is to provide an audio circuit in a display which can output audio signals from the display.

### SUMMARY

An embodiment of an audio circuit arranged in a display includes an audio input connector configured to connect to an audio output connector of a computer to receive audio signals therefrom, an audio input circuit receiving the audio signals, an audio amplifier circuit connected to the audio input circuit to amplify the audio signals, an audio output circuit outputting the amplified audio signals, a first output connector connected to the audio output circuit, a volume adjusting circuit, a micro control unit (MCU) of a motherboard of the display connected to the volume adjusting circuit, and a speaker connected to the first output connector. The volume adjusting circuit receives a control signal from the MCU to control the volume adjusting circuit to adjust the audio signals, and the speaker receives the adjusted audio signals.

Other advantages and novel features of the present invention will become more apparent from the following detailed description of an embodiment when taken in conjunction with the accompanying drawings, in which:

### BRIEF DESCRIPTION OF THE DRAWINGS

FIG. 1 is a block diagram of an audio circuit in accordance with an embodiment of the present invention;

FIG. 2 is a circuit diagram of the audio circuit of FIG. 1;

FIG. 3 is a voltage waveform chart of the volume control pins of the audio amplifier of the audio circuit of FIG. 2 when a duty cycle of the pulse width modulation (PWM) control signal is 1:2; and

FIG. 4 is a voltage waveform chart of the volume control pins of the audio amplifier of the audio circuit of FIG. 2 when the duty cycle of the PWM control signal is 1:4.

### DETAILED DESCRIPTION

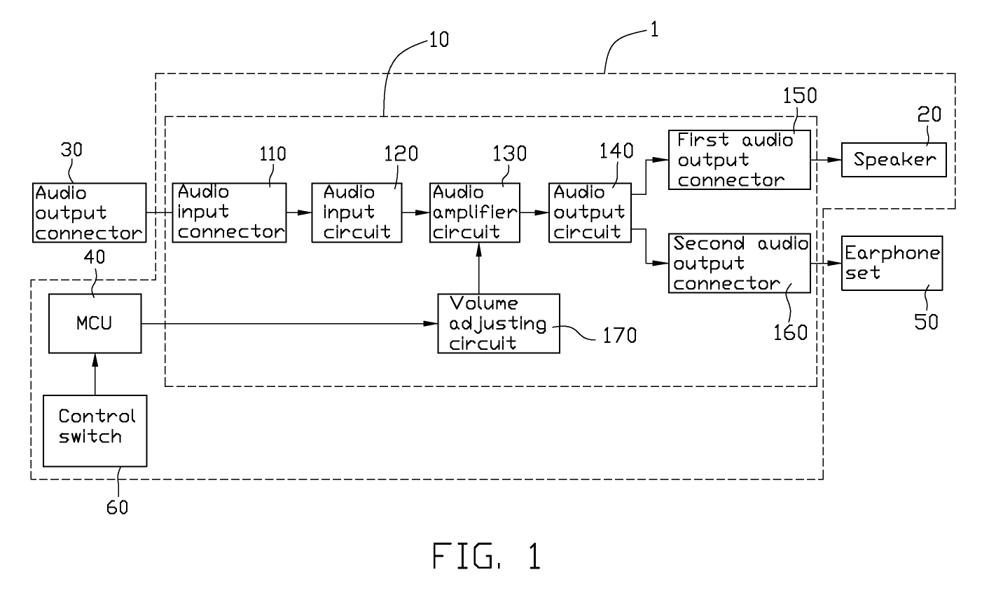

Referring to FIG. 1, an audio circuit for a display 1 (such as a monitor of a computer system) in accordance with an embodiment of the present invention includes an audio circuit 10 and a speaker 20. The audio circuit 10 is configured to receive audio signals from a computer via an audio output connector 30 of the computer and an audio cable, and the audio signals are processed by the audio circuit 10 and then output via the speaker 20 or an earphone set 50. In this embodiment, the audio circuit 10 is arranged in a motherboard of the display 1, and the speaker 20 is mounted in or on the display 1.

The audio circuit 10 includes an audio input connector 110, an audio input circuit 120, an audio amplifier circuit 130, an audio output circuit 140, a first output connector 150, a second audio output connector 160, and a volume adjusting circuit 170. The audio input connector 110 is configured to connect to the audio output connector 30 of the computer via the audio cable and connected to the audio amplifier circuit 130 via the audio input circuit 120. The audio amplifier circuit 130 is connected to the first output connector 150 and the second audio output connector 160 via the audio output circuit 140. The first output connector 150 is connected to the speaker 20. The second output connector 160 is configured to connect to the earphone set 50. A micro control unit (MCU) 40 of the motherboard of the display 1 is connected to the amplifier circuit 130 via the volume adjusting circuit 170. In this embodiment, the audio circuit further includes a control switch 60 mounted on the display 1 and connected to the MCU 40 of the motherboard of the display 1 to control the MCU 40 to output pulse width modulation (PWM) control signals.

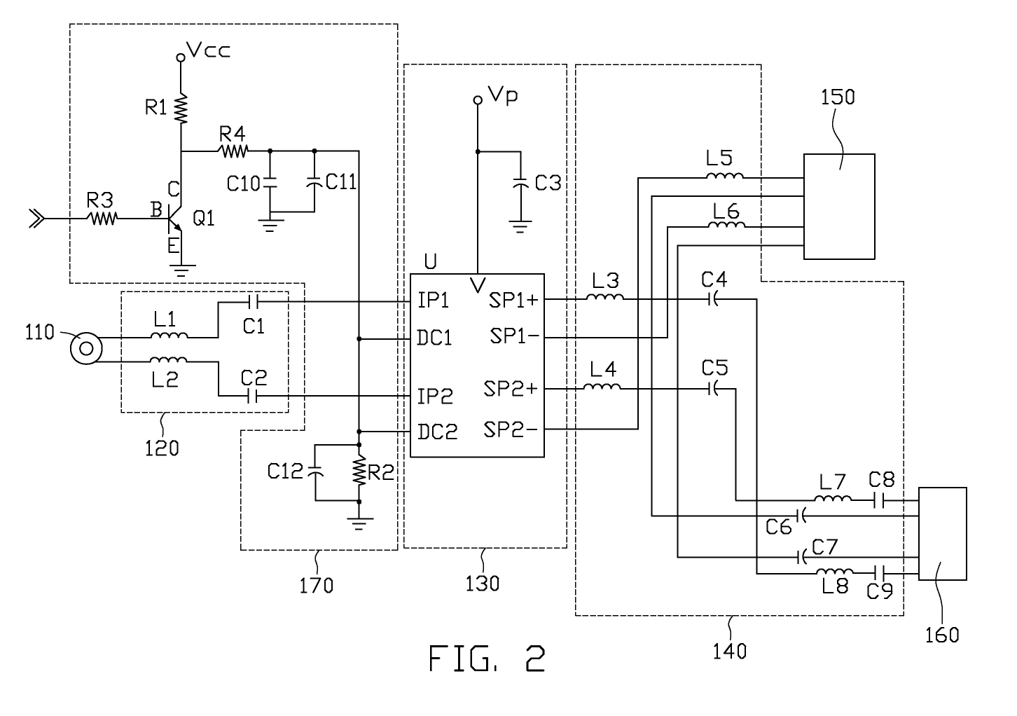

Referring also to FIG. 2, the audio input circuit 120 includes a first inductor L1, a second inductor L2, a first capacitor C1, and a second capacitor C2. The amplifier circuit 130 includes an audio amplifier U, a power supply Vp, and a third capacitor C3. The audio output circuit 140 includes a third inductor L3, a fourth inductor L4, a fifth inductor L5, a sixth inductor L6, a seventh inductor L7, an eighth inductor L8, a fourth capacitor C4, a fifth capacitor C5, a sixth capacitor C6, a seven capacitor C7, an eighth capacitor C8, and a ninth capacitor C9. The volume adjusting circuit 170 includes a transistor Q1, a first resistor R1, a second resistor R2, a third resistor R3, a fourth resistor R4, a tenth capacitor C10, an eleventh capacitor C11, and a twelfth capacitor C12.

Two audio pins of the audio input connector 110 are respectively connected to two signal input pins of the audio amplifier U via the first inductor L1 and the first capacitor C1 in turn and the second inductor L2, and the second capacitor C2 in turn respectively. The base of the transistor Q1 is configured to receive the PWM control signal from the MCU 40 via the third resistor R3. The emitter of the transistor Q1 is grounded. The collector of the transistor Q1 is connected to a power supply Vcc via the first resistor R1 and connected to ground via the fourth and second resistors R4 and R2 in turn. The tenth capacitor C10 and the eleventh capacitor C11 are connected between a node of fourth and second resistors R4 and R2 and ground. The twelfth capacitor C12 is connected in parallel to the second resistor R2. Two volume control pins DC1 and DC2 of the amplifier U are connected to the node of the fourth and second resistors R4 and R2. A power pin of the audio amplifier U is connected to the power supply Vp and grounded via the third capacitor C3.

A first signal output pin SP1+ is connected to the second audio output connector 160 via the third inductor L3, the fourth capacitor C4, the eighth inductor L8, and the ninth capacitor C9 in turn. A second signal output pin SP1− is connected to the first audio output connector 150 via the sixth inductor L6. A third signal output pin SP2+ is connected to the second audio output connector 160 via the fourth inductor L4, the fifth capacitor C5, the seventh inductor L7, and the eighth capacitor C8 in turn. A fourth signal output pin SP2− is connected to the first audio output connector 150 via the fifth inductor L5.

In this embodiment, the fourth, fifth, sixth, seventh, and tenth capacitors C4˜C7 and C10 are low voltage filter capacitors configured to filter low voltage noise. The eighth capacitor C8, the ninth capacitor C9, and the eleventh capacitor C11 are high voltage filter capacitors configured to filter high voltage noise.

In use, the audio output connector 30 of the computer is connected to the audio input connector 110. When the computer outputs audio signals to the audio circuit 10 via the audio input connector 110, the audio signals are processed by the audio circuit 10 and then output via the speaker 20 or the earphone set 50.

Moreover, users can control volume of the speaker 20 and the earphone set 50 via the control switch 60. The control switch 60 can control the MCU 40 to change the duty cycle of the PWM control signal therefrom. When the PWM control signal is at a high voltage, the transistor Q1 is turned on, and then the volume control pins DC1 and DC2 of the amplifier U are at a low voltage. When the PWM control signal is at a low voltage, the transistor Q1 is turned off, and then the volume control pins DC1 and DC2 of the amplifier U are at a high voltage. Different duty cycles of the PWM control signal can control the amplifier U to change volume of audio output of the speaker 20 and the earphone set 50.

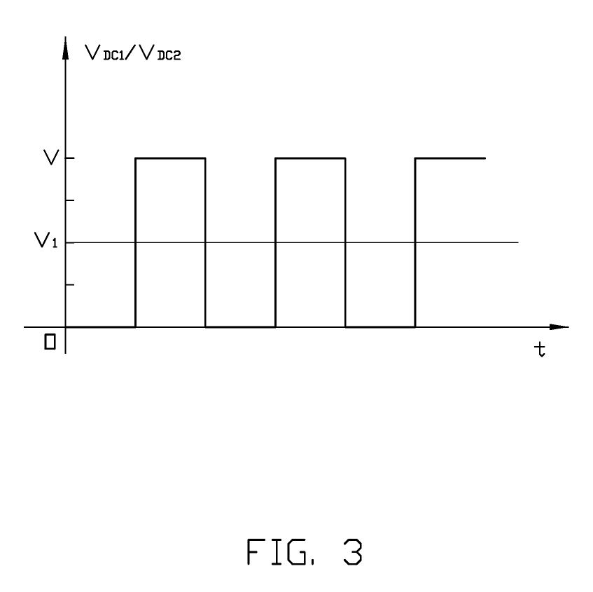

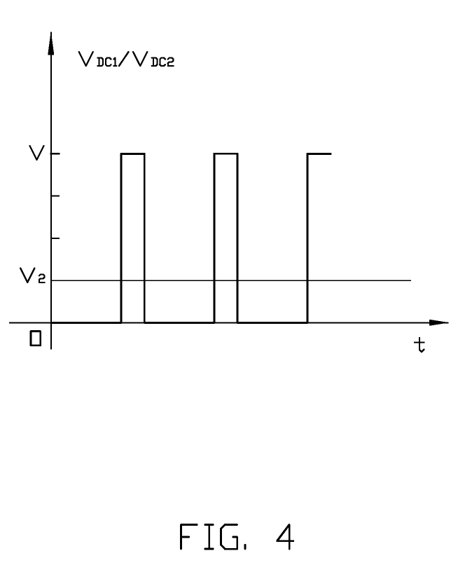

Referring also to FIGS. 3 and 4, when the duty cycle of the PWM control signal is 1:2, the equivalent voltage V1 of the volume control pins DC1 and DC2 of the amplifier U is ½ the voltage of the high voltage V of the PWM control signal. When the duty cycle of the PWM control signal is 1:4, the equivalent voltage V1 of the volume control pins DC1 and DC2 of the amplifier U is ¼ the voltage of the high voltage V of the PWM control signal. Thereby, users can adjust volume of the speaker 20 and the earphone set 50 from the computer by changing the duty cycle of the PWM control signal via the control switch 60, which is very convenient.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An audio circuit arranged in a display, comprising:
an audio input connector configured to connect to an audio output connector of a computer to receive audio signals therefrom;
an audio input circuit receiving the audio signals;
an audio amplifier circuit connected to the audio input circuit to amplify the audio signals;
an audio output circuit outputting the amplified audio signals;
a first output connector connected to the audio output circuit;
a volume adjusting circuit, a micro control unit (MCU) of a motherboard of the display connected to the volume adjusting circuit, the volume adjusting circuit receiving a control signal from the MCU to control the volume adjusting circuit to adjust the audio signals; and
a speaker connected to the first output connector to receive the adjusted audio signals.

2. The audio circuit as claimed in claim 1, further comprising a control switch connected to the MCU to control the MCU to output the control signal.

3. The audio circuit as claimed in claim 1, wherein the control signal is a pulse width modulation (PWM) signal.

4. The audio circuit as claimed in claim 1, wherein the volume adjusting circuit comprises a transistor, a first resistor, and a second resistor, the base of the transistor is connected to the MCU, the emitter of the transistor is grounded, the collector of the transistor is connected to a power supply via the first resistor, connected to ground via the second resistor, and connected to the audio amplifier circuit.

5. The audio circuit as claimed in claim 1, wherein the audio input circuit comprises a first inductor, a second inductor, a first capacitor, and a second capacitor, two audio pins of the audio input connector are respectively connected to the audio amplifier circuit via the first inductor and the first capacitor in turn, and the second inductor and the second capacitor in turn respectively.

6. The audio circuit as claimed in claim 1, wherein the amplifier circuit comprises an audio amplifier, volume control pins of the audio amplifier are connected to the volume adjusting circuit, signal input pins of the audio amplifier are connected to the audio input circuit, signal output pins of the audio amplifier are connected to the audio output circuit.

7. The audio circuit as claimed in claim 6, further comprising a second output connector connected to the audio amplifier circuit via the audio output circuit and configured for connecting an earphone set.

8. The audio circuit as claimed in claim 7, wherein the audio output circuit comprises a third inductor, a fourth inductor, a fifth inductor, a sixth inductor, a seventh inductor, an eighth inductor, a fourth capacitor, a fifth capacitor, a sixth capacitor, a seven capacitor, an eighth capacitor, and a ninth capacitor, a first signal output pin is connected to the second audio output connector via the third inductor, the fourth capacitor, the eighth inductor, and the ninth capacitor in turn, a second signal output pin is connected to the first audio output connector via the sixth inductor, a third signal output pin is connected to the second audio output connector via the fourth inductor, the fifth capacitor, the seventh inductor, and the eighth capacitor in turn, a fourth signal output pin is connected to the first audio output connector via the fifth inductor.

9. A display having volume adjusting function, comprising:
an audio input connector configured to connect to an audio output connector of a computer to receive audio signals therefrom;
an audio input circuit receiving the audio signals;
an audio amplifier circuit connected to the audio input circuit to amplify the audio signals;
an audio output circuit outputting the amplified audio signals;
a first output connector connected to the audio output circuit;
a volume adjusting circuit connected to audio amplifier circuit;
a micro control unit (MCU) connected to the volume adjusting circuit, the volume adjusting circuit receiving a pulse width modulation (PWM) signal from the MCU to control the volume adjusting circuit to adjust the audio signals; and
a speaker connected to the first output connector to receive the adjusted audio signals to change volume thereof.

10. The display having volume adjusting function as claimed in claim 9, further comprising a control switch connected to the MCU to control the MCU to output the PWM signal.

11. The display having volume adjusting function as claimed in claim 9, wherein the volume adjusting circuit comprises a transistor, a first resistor, and a second resistor, the base of the transistor is connected to the MCU, the emitter of the transistor is grounded, the collector of the transistor is connected to a power supply via the first resistor, connected to ground via the second resistor, and connected to the audio amplifier circuit.

12. The display having volume adjusting function as claimed in claim 9, wherein the audio input circuit comprises a first inductor, a second inductor, a first capacitor, and a second capacitor, two audio pins of the audio input connector are respectively connected to the audio amplifier circuit via the first inductor and the first capacitor in turn, and the second inductor and the second capacitor in turn respectively.

13. The display having volume adjusting function as claimed in claim 9, wherein the amplifier circuit comprises an audio amplifier, volume control pins of the audio amplifier are connected to the volume adjusting circuit, signal input pins of the audio amplifier are connected to the audio input circuit, signal output pins of the audio amplifier are connected to the audio output circuit.

14. The display having volume adjusting function as claimed in claim 13, further comprising a second output connector connected to the audio amplifier circuit via the audio output circuit and configured for connecting an earphone set.

15. The display having volume adjusting function as claimed in claim 14, wherein the audio output circuit comprises a third inductor, a fourth inductor, a fifth inductor, a sixth inductor, a seventh inductor, an eighth inductor, a fourth capacitor, a fifth capacitor, a sixth capacitor, a seven capacitor, an eighth capacitor, and a ninth capacitor, a first signal output pin is connected to the second audio output connector via the third inductor, the fourth capacitor, the eighth inductor, and the ninth capacitor in turn, a second signal output pin is connected to the first audio output connector via the sixth inductor, a third signal output pin is connected to the second audio output connector via the fourth inductor, the fifth capacitor, the seventh inductor, and the eighth capacitor in turn, a fourth signal output pin is connected to the first audio output connector via the fifth inductor.
